(19) United States
(12) Patent Application Publication
(10) Pub. No.: US 2025/0183622 A1
(43) Pub. Date: Jun. 5, 2025

(54) SEMICONDUCTOR DEVICE, METHOD FOR MANUFACTURING SEMICONDUCTOR DEVICE, AND METHOD FOR IDENTIFYING SEMICONDUCTOR DEVICE

(71) Applicant: Mitsubishi Electric Corporation, Tokyo (JP)

(72) Inventors: Hodaka SHIRATAKI, Tokyo (JP); Kazuyuki ONOE, Tokyo (JP)

(73) Assignee: Mitsubishi Electric Corporation, Tokyo (JP)

(21) Appl. No.: 18/845,307

(22) PCT Filed: Mar. 30, 2022
(86) PCT No.: PCT/JP2022/016015

§ 371 Date: Sep. 9, 2024

(51) Int. Cl. H01S 5/22; H01S 5/223

(52) U.S. Cl. CPC H01S 5/2226; H01S 5/2206; H01S 5/2224; H01S 5/223

(57) ABSTRACT

A semiconductor device according to the present disclosure includes: a semiconductor substrate; semiconductor layers formed on the semiconductor substrate; an identification pattern region provided in a predetermined portion on the semiconductor substrate; and needle-shaped structures or dome-shaped structures in which the needle-shaped structures are covered with a SiO₂ insulating film, which are formed at random positions within the identification pattern region.

### TECHNICAL FIELD

The present disclosure relates to a semiconductor device, a method for manufacturing a semiconductor device, and a method for identifying a semiconductor device.

### BACKGROUND ART

In the case of general semiconductor laser devices, a numeral or alphabet may be printed on each chip to identify coordinate information in a wafer surface. This is to improve chip traceability by providing identification information for each chip.

### CITATION LIST

Patent Document 1: Japanese Laid-Open Patent Publication No. 2000-223382

### SUMMARY OF THE INVENTION

### Problem to be Solved by the Invention

In semiconductor devices in general, including semiconductor laser devices, wafers are processed and completed by a wafer process, and then separated into bars and even chip units by a cleaving separation process before being shipped to back-end processes or customers. In this case, there is a problem that it is difficult to associate the bar or the chip unit product with the manufacturing condition under which the product is processed in the wafer process.

To solve the above problem, for example, the micro marking method described in Patent Document 1 forms an identification pattern on each chip during the wafer process using a transfer process. However, in the case where a regular pattern is formed on the chip as the identification pattern, there is a risk that chip information such as manufacturing date may be leaked to the outside.

In the case of forming a random pattern on the chip as the identification pattern, on the other hand, it is necessary to prepare a different mask pattern for each lot, which complicates the manufacturing process.

The present disclosure has been made to solve the above problem, and an object of the present disclosure is to provide a semiconductor device and a method for manufacturing the semiconductor device in which a random identification pattern is formed on each chip without a transfer process and can be utilized for chip identification, and to provide a method for identifying the semiconductor device by using the random identification pattern on the semiconductor device to identify each chip.

### Means to Solve the Problem

A semiconductor device according to the present disclosure includes: a semiconductor substrate; semiconductor layers formed on the semiconductor substrate; an identification pattern region provided in a predetermined portion on the semiconductor substrate; and a plurality of structures formed at random positions within the identification pattern region.

A method for manufacturing a semiconductor device according to the present disclosure includes: crystal-growing sequentially an active layer and a second-conductivity-type InP cladding layer on a first-conductivity-type InP substrate; forming a stripe-shaped ridge structure by etching a part of the first-conductivity-type InP substrate, the active layer, and the second-conductivity-type InP cladding layer; crystal-growing a ridge-buried layer composed of at least a Fe-doped semi-insulating InP first current blocking layer and a Fe-doped semi-insulating InP second current blocking layer so as to bury on both side surfaces of the ridge structure; crystal-growing sequentially a remaining portion of the second-conductivity-type InP cladding layer and a second conductivity type contact layer on a top surface of the ridge structure and a surface of the ridge-buried layer; etching mesa-stripe grooves reaching from the second-conductivity-type contact layer into the Fe-doped semi-insulating InP second current blocking layer on both sides of the ridge structure, and simultaneously forming an opening portion in the region predetermined for the identification pattern region; and etching away the Fe-doped semi-insulating InP second current blocking layer and the Fe-doped semi-insulating InP first current blocking layer in the opening portion and simultaneously forming needle-shaped structures.

A method for identifying a semiconductor device according to the present disclosure includes: a step of capturing an image of the identification pattern region from the top surface of the semiconductor device described above; a step of converting the image into a binarized map; a step of ranking each black dot in the binarized map higher the larger the area of the black dot on a basis of the area of the black dot; and a step of selecting a predetermined number of black dots from each of the ranked black dots in order of rank.

### Effect of the Invention

In the semiconductor device according to the present disclosure, the identification pattern region including randomly located structures is provided in the chip, thus providing an effect of easily identifying each chip and thus obtaining a semiconductor device in which chip manufacturing information is automatically encrypted.

In the method for manufacturing a device according to the present semiconductor disclosure, the identification pattern region including the structures randomly located on each chip can be easily formed without a transfer process, thus providing an effect of easily manufacturing a semiconductor device in which each chip can be easily identified and the chip manufacturing information is automatically encrypted.

In the method for identifying a semiconductor device according to the present disclosure, each semiconductor device is identified using the identification pattern region having the randomly located structures, thus providing an effect of easily identifying each chip of the semiconductor device in which the chip manufacturing information is automatically encrypted.

### BRIEF DESCRIPTION OF THE DRAWINGS

FIG. 1 is a top view of a semiconductor

device according to Embodiment 1;

FIG. 2 is a cross-sectional view of the semiconductor device according to Embodiment 1 taken along line A-A shown in FIG. 1;

FIG. 3 is a cross-sectional view of the semiconductor device according to Embodiment 1 taken along line B-B shown in FIG. 1;

FIG. 4 is a cross-sectional view of the semiconductor device according to Embodiment 1 taken along line C-C of FIG. 1;

FIG. 5 is a cross-sectional view taken along line A-A of FIG. 1, showing a method for manufacturing a semiconductor device according to Embodiment 1;

FIG. 6 is a cross-sectional view taken along line A-A of FIG. 1, showing the method for manufacturing a semiconductor device according to Embodiment 1;

FIG. 7 is a cross-sectional view taken along line A-A of FIG. 1, showing the method for manufacturing a semiconductor device according to Embodiment 1;

FIG. 8 is a cross-sectional view taken along line A-A of FIG. 1, showing the method for manufacturing a semiconductor device according to Embodiment 1;

FIG. 9 is a cross-sectional view taken along line A-A of FIG. 1, showing the method for manufacturing a semiconductor device according to Embodiment 1;

FIG. 10 is a cross-sectional view showing an example of another device structure of the semiconductor device according to Embodiment 1;

FIG. 11 is a schematic view showing a state where a semiconductor device array including the semiconductor devices according to Embodiment 1 is formed on a wafer;

FIG. 12 is a schematic diagram of an image showing needle-shaped structures in an identification pattern region of the semiconductor device according to Embodiment 1;

FIG. 13 shows a map obtained by binarizing the image of the needle-shaped structures in the identification pattern region of the semiconductor device according to Embodiment 1;

FIG. 14 is a diagram in which a map obtained by binarizing the image of the needle-shaped structures in the identification pattern region of the semiconductor device according to Embodiment 1 is partitioned into sections and the sections in which black dots exist are visualized;

FIG. 15 shows the sections where the top 15 black dots exist in the case where the black dots are ranked in order of area in the binarized map of the needle-shaped structures in the identification pattern region of the semiconductor device according to Embodiment 1;

FIG. 16 shows a state in which black dots are ranked in order of area in the binarized map of the needle-shaped structures in the identification pattern region of the semiconductor device according to Embodiment 1, and coordinates are defined for each of the sections where the top 15 black dots exist;

FIG. 17 is a top view of a semiconductor device according to Embodiment 2;

FIG. 18 is a cross-sectional view of the semiconductor device according to Embodiment 2, taken along line A-A shown in FIG. 17;

FIG. 19 is a cross-sectional view of dome-shaped structures in the identification pattern region of the semiconductor device according to Embodiment 2;

FIG. 20 shows an image of the dome-shaped structures in the identification pattern region of the semiconductor device according to Embodiment 2;

FIG. 21 shows a map obtained by binarizing the image of the dome-shaped structures in the identification pattern region of the semiconductor device according to Embodiment 2;

FIG. 22 is a diagram in which a map obtained by binarizing the image of the dome-shaped structures in the identification pattern region of the semiconductor device according to Embodiment 2 is partitioned into sections and the sections in which black dots exist are visualized;

FIG. 23 shows the sections where the top five black dots exist in the case where the black dots are ranked in order of area in the binarized map of the dome-shaped structures in the identification pattern region of 41 the semiconductor device according to Embodiment 2;

FIG. 24 shows a state in which black dots are ranked in order of area in the binarized map of the dome-shaped structures in the identification pattern region of the semiconductor device according to Embodiment 2, and coordinates are defined for each of the sections where the top five black dots exist;

FIG. 25 is a top view of a semiconductor device according to Embodiment 3;

FIG. 26 is a top view of the semiconductor device according to Modification of Embodiment 3;

FIG. 27 is a top view of a semiconductor device according to Embodiment 4;

FIG. 28 is a top view of a semiconductor device according to Modification of Embodiment 4;

FIG. 29 is a top view of a semiconductor device according to Embodiment 5;

FIG. 30 is a top view of a semiconductor device according to Embodiment 6;

FIG. 31 shows a concept of a matching rate of character-string codes in a method for identifying a semiconductor device according to Embodiment 7;

FIG. 32 is a diagram showing the probability that the same character-string code is generated among a plurality of semiconductor devices for each matching rate of the character-string codes in the method for identifying a semiconductor device according to Embodiment 7;

FIG. 33 is a diagram showing the probability that the same character-string code is generated among a plurality of semiconductor devices for each matching rate of the character-string code in the method for identifying a semiconductor device according to Embodiment 7.

### DESCRIPTION OF EMBODIMENTS

### Embodiment 1

### Structure of Semiconductor Device According to Embodiment 1

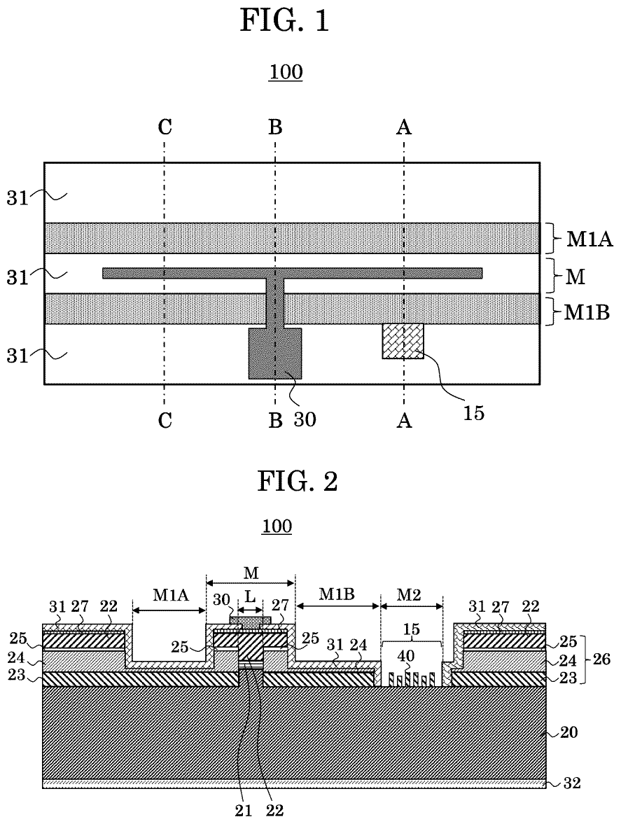

In Embodiment 1, a semiconductor laser device will be described as an example of the semiconductor device 100 according to Embodiment 1. FIG. 1 is a top view of a semiconductor device 100 according to Embodiment 1. Hereinafter, the semiconductor device may be referred to as a chip. On the top side of the chip, the semiconductor device 100 includes: a stripe-shaped mesa structure M; a pair of a mesa-stripe groove MIA and a mesa-stripe groove M1B provided on both sides of the mesa structure M; a front surface electrode 30 provided to inject a current into a ridge structure L described later; and an identification pattern region 15 for chip identification adjacent to one of the mesa-stripe grooves M1B. To protect the chip surface, the front surface region of the chip except for the front surface electrode 30 and the identification pattern region 15 is covered with a SiO₂ insulating film 31. The surfaces of the pair of mesa-stripe groove MIA and the mesa-stripe groove M1B are also covered with the SiO₂ insulating film 31 (not shown). In the following description, the SiO₂ insulating film 31 may be simply referred to as an insulating film 31.

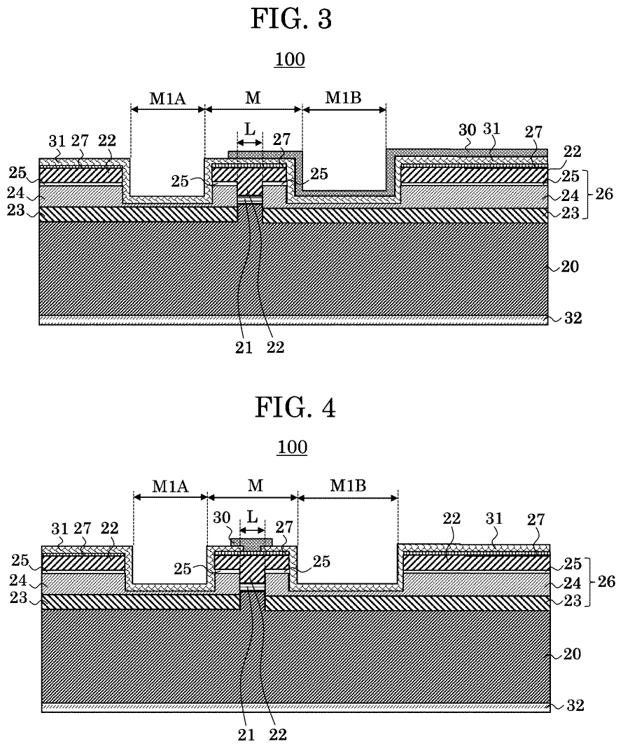

FIGS. 2 to 4 are cross-sectional views of respective parts of the semiconductor device 100 according to Embodiment 1. FIG. 2 is a cross-sectional view of the semiconductor device 100 taken along line A-A shown in FIG. 1. FIG. 3 is a cross-sectional view taken along line B-B shown in FIG. 1. FIG. 4 is a cross-sectional view taken along line C-C shown in FIG. 1.

The structure of the semiconductor device 100 according to Embodiment 1 will be described with reference to the cross-sectional view of FIG. 2. First, the portion of the ridge structure L will be described. The semiconductor device 100 according to Embodiment 1 includes: an n-type InP substrate (first-conductivity-type InP substrate) 20; the stripe-shaped ridge structure L composed of undoped InGaAsP active layer 21, and a p-type InP cladding layer (second-conductivity-type InP cladding layer) 22, which are sequentially crystal-growing on the n-type InP substrate 20, and a part of the n-type InP substrate 20; a ridge-buried layer 26 composed of a Fe-doped semi-insulating InP first current blocking layer 23, a Fe-doped semi-insulating InP second current blocking layer 24, and an n-type InP anti-diffusion layer 25, which are formed on the n-type InP substrate 20 on both sides of the ridge structure L; a p-type InGaAsP contact layer (second-conductivity-type contact layer) 27 formed on the remaining portion of the p-type InP cladding layer 22; the front surface electrode 30 in contact with the p-type InGaAsP contact layer 27 in an opening portion provided in the SiO₂ insulating film 31 formed on the surface of the p-type InGaAsP contact layer 27; and a back surface electrode 32 provided on the back surface side of the n-type InP substrate 20. The layers made of semiconductors are also collectively referred to as semiconductor layers. Note that the remaining portion of the p-type InP cladding layer 22 means a portion of the p-type InP cladding layer 22 formed during the second crystal growth, while the entire p-type InP cladding layer 22 is formed through two crystal growth cycles as described later.

The mesa structure M is defined by a pair of the mesa-stripe groove M1A and the mesa-stripe groove M1B located on both sides of the mesa structure M. An opening portion M2 is further provided adjacent to the mesa-stripe groove M1B, and the identification pattern region 15 for chip identification is formed. An example of the size of the identification pattern region 15 is 10 μm×10 μm. However, the size thereof is not limited to such size, and any size may be used as long as the size thereof functions as the identification pattern for the semiconductor device 100.

The Fe-doped semi-insulating InP first current blocking layer 23 and the Fe-doped semi-insulating InP second current blocking layer 24 are the same in terms of material composition, but are different in Fe doping concentration. The Fe-doped semi-insulating InP second current blocking layer 24 has a low Fe doping concentration of 5×10¹⁵ cm⁻³ or less, whereas the Fe-doped semi-insulating InP first current blocking layer 23 has a high Fe doping concentration of 1×10¹⁶ cm⁻³ or more. This is because, in the case where the Fe doping concentration in InP is 1×10¹⁶ cm⁻³ or more, the probability of the presence of inactive Fe elements in InP increases, and thus Fe elements tend to aggregate during etching. An example of the Fe doping concentration of the Fe-doped semi-insulating InP second current blocking layer 24 is 5×10¹⁵ cm⁻³, and an example of the Fe doping concentration of the Fe-doped semi-insulating InP first current blocking layer 23 is 5×10¹⁶ cm⁻³.

The SiO₂ insulating film 31 made of SiO₂ is formed on the top surface of each semiconductor layer except for the front surface electrode 30 and the opening portion M2 in order to protect the top surface of each semiconductor layer by the SiO₂ insulating film 31.

In the opening portion M2, that is, in the identification pattern region 15, when the Fe-doped semi-insulating InP first current blocking layer 23 is etched during the manufacturing process described below, needle-shaped structures 40 made of InP (indium phosphorus) are formed at random positions on the n-type InP substrate 20 exposed by the etching.

FIG. 3 is a cross-sectional view of the semiconductor device 100 according to Embodiment 1 taken along line B-B shown in FIG. 1. The front surface electrode 30 extend from the top surface of the mesa structure M to the front surface electrode pads outside the mesa-stripe groove M1B through the mesa-stripe groove M1B. This is because a gold wire, which is a signal input line, is connected to the front surface electrode pad portion.

FIG. 4 is a cross-sectional view of the semiconductor device 100 according to Embodiment 1 taken along line C-C shown in FIG. 1. The top surface of each semiconductor layer except for the front surface electrode 30 is covered with the SiO₂ insulating film 31 in order to protect the top surface of each semiconductor layer by the SiO₂ insulating film 31.

### Method for Manufacturing Semiconductor Device According to Embodiment 1

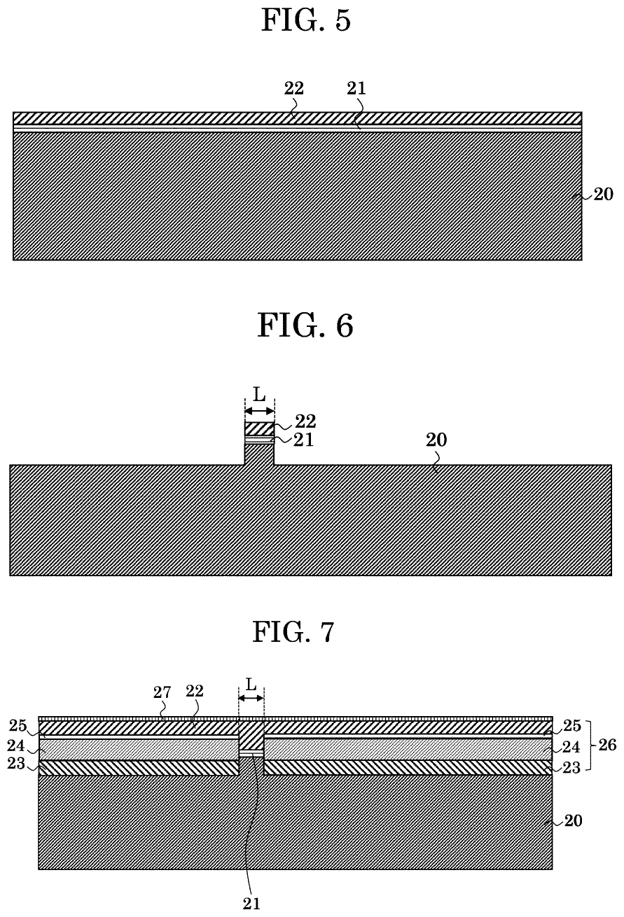

A method for manufacturing the semiconductor device 100 according to Embodiment 1 will be described with reference to FIGS. 5 to 10.

The undoped InGaAsP active layer 21 and the p-type InP cladding layer 22 are sequentially crystal-grown on the n-type InP substrate 20 by a crystal growth method such as a metal organic chemical vapor deposition (MOCVD) method (first crystal growth step). FIG. 5 shows a cross-sectional view of each semiconductor layer after the crystal growth.

After the first crystal growth step, a SiO₂ film is deposited on the surface of the p-type InP cladding layer 22. A method of depositing the SiO₂ film includes, for example, a chemical vapor deposition (CVD) method, or the like. After the SiO₂ film is deposited, the SiO₂ film is patterned into a stripe-shaped SiO₂ mask by photolithography and etching techniques.

Next, using a stripe-shaped SiO₂ mask as an etching mask, the stripe-shaped ridge structure L is formed by over-etching from the p-type InP cladding layer 22 to the middle of the n-type InP substrate 20 by dry etching, as shown in the cross section in FIG. 6 (ridge structure forming step). Here, the etching mask is not limited to the SiO₂ mask, but may also be a SiN mask. The etching is not limited to dry etching, but wet etching may be used. Furthermore, both dry etching and wet etching may be used.

After the formation of the stripe-shaped ridge structure L, the ridge-buried layer 26 composed of the Fe-doped semi-insulating InP first current blocking layer 23, the Fe-doped semi-insulating InP second current blocking layer 24, and the n-type InP anti-diffusion layer 25 are crystal-grown by the MOCVD method so as to cover both side surfaces of the ridge structure L (second crystal growth step).

After the growth of the ridge-buried layer 26, the stripe-shaped SiO₂ mask is removed by wet etching using hydrofluoric acid as an etchant.

On the top surface of the ridge structure L and the surface of the ridge-buried layer 26, the remaining portion of the p-type InP cladding layer 22 and the p-type InGaAsP contact layer 27 are sequentially crystal-grown by the MOCVD method (third crystal growth step). FIG. 7 is a cross-sectional view of each of the above semiconductor layers after the crystal growth.

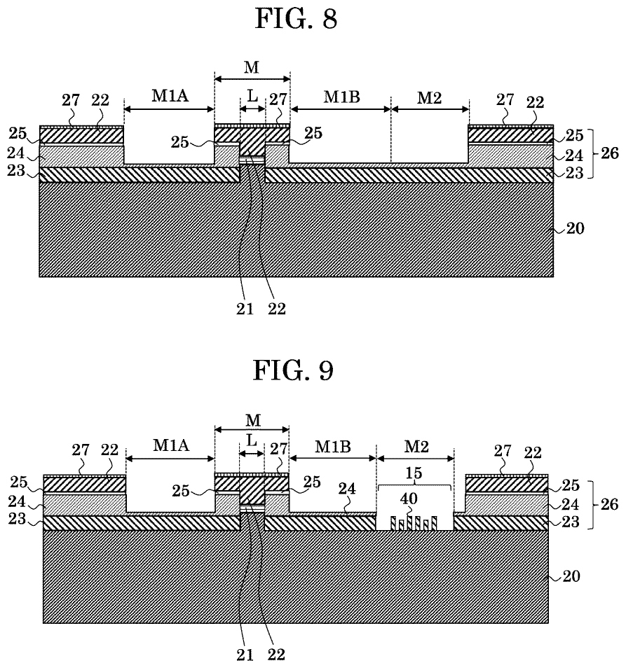

After the third crystal growth step, a SiO₂ mask is formed on a portion other than a portion where the pair of the mesa-stripe groove MIA and the mesa-stripe groove M1B are to be formed by photolithography and etching techniques, and then dry etching is performed from the p-type InGaAsP contact layer 27 to the middle of the Fe-doped semi-insulating InP second current blocking layer 24 (mesa structure forming step). The dry etching etches from the p-type InGaAsP contact layer 27 to the middle of the Fe-doped semi-insulating InP second current blocking layer 24 in the opening portion M2 in the same way. After the dry etching, the stripe-shaped SiO₂ mask is removed by wet etching using hydrofluoric acid as an etchant. FIG. 8 is a cross-sectional view after the SiO₂ mask is removed.

By the above-described dry etching, the pair of the mesa-stripe groove MIA and the mesa-stripe groove M1B are formed, and at the same time, the mesa structure M defined by the pair of the mesa-stripe groove MIA and the mesa-stripe groove M1B is also formed.

After forming the pair of the mesa-stripe groove MIA and the mesa-stripe groove M1B, a resist mask having an opening pattern portion corresponding to the opening portion M2 where the identification pattern region 15 is to be formed in the mesa-stripe groove M1B is formed by photolithography and etching techniques. The remaining portion of the Fe-doped semi-insulating InP second current blocking layer 24 and the Fe-doped semi-insulating InP first current blocking layer 23 in the opening pattern portion of the resist mask are removed by dry etching. As a result, the n-type InP substrate 20 is exposed at the bottom surface of the opening portion M2.

During etching of the Fe-doped semi-insulating InP first current blocking layer 23, the high Fe doping concentration of the Fe-doped semi-insulating InP first current-blocking layer 23 results in a higher probability of inactive Fe elements in InP, and as a result, Fe elements tend to aggregate and thus micro-masks with Fe elements are formed. Since the micro-masks made of Fe elements function as an etching mask, the areas covered by the micro-masks remain unetched, thus forming the needle-shaped structures 40 made of indium phosphorus on the n-type InP substrate 20. The diameter, height, and position of the needle-shaped structures 40 occurring within the opening portion M2 are completely random.

Furthermore, the SiO₂ insulating film 31 is formed on the entire surface of the wafer except for the opening portion M2, and then an opening portion is formed in the SiO₂ insulating film 31 at a position corresponding to the upper side of the ridge structure L on the p-type InGaAsP contact layer 27 by photolithography and dry etching techniques. The front surface electrode 30 is formed in contact with the surface of the p-type InGaAsP contact layer 27 in such opening portion, and then the back surface electrode 32 is formed on the back surface side of the n-type InP substrate 20 (electrode forming step).

Through the above-described manufacturing steps, the basic structure of the semiconductor laser device as an example of the semiconductor device 100 is completed.

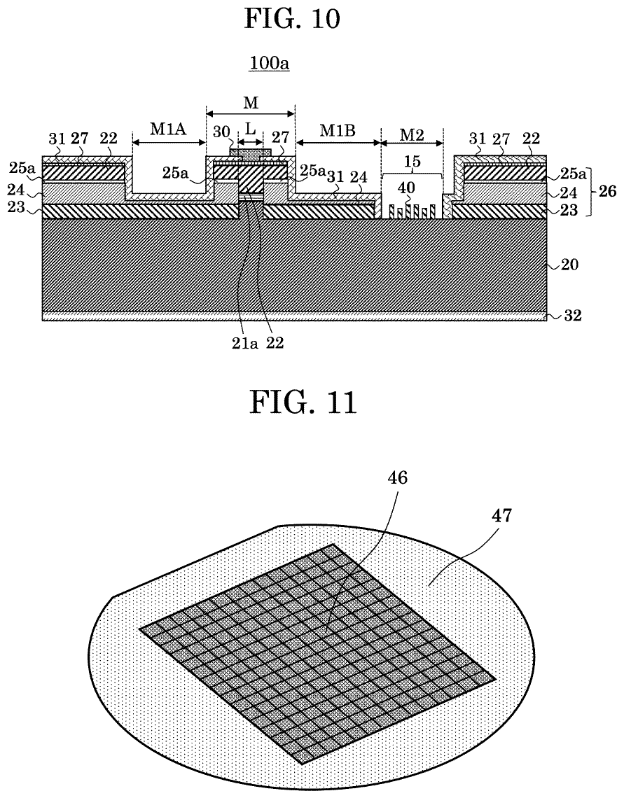

The method for manufacturing the semiconductor device 100 according to Embodiment 1 has been described above. The materials constituting the semiconductor layers of the semiconductor device 100 are not limited to above-mentioned materials. FIG. 10 is a cross-sectional view showing an example of a semiconductor device having another structure according to Embodiment 1. Instead of the undoped InGaAsP active layer 21 and the n-type InP anti-diffusion layer 25 of the semiconductor device 100 shown in FIG. 2, the semiconductor device 100a may be configured with an undoped AlGaInAs active layer 21a and an undoped InP anti-diffusion layer 25a, as in the semiconductor device 100a shown in FIG. 10.

### Method for Identifying Semiconductor Device

The following describes a method of identifying a semiconductor device 100 completed through the manufacturing process described above, using an identification pattern region 15 formed in the semiconductor device 100 with the needle-shaped structures 40 at random positions.

FIG. 11 is a schematic view showing a wafer 47 provided as a semiconductor device array 46 in which a large number of semiconductor devices 100 according to Embodiment 1 are two dimensionally arranged. After the completion of the manufacturing process of the semiconductor device 100, the wafer 47 is in a state as shown in FIG. 11.

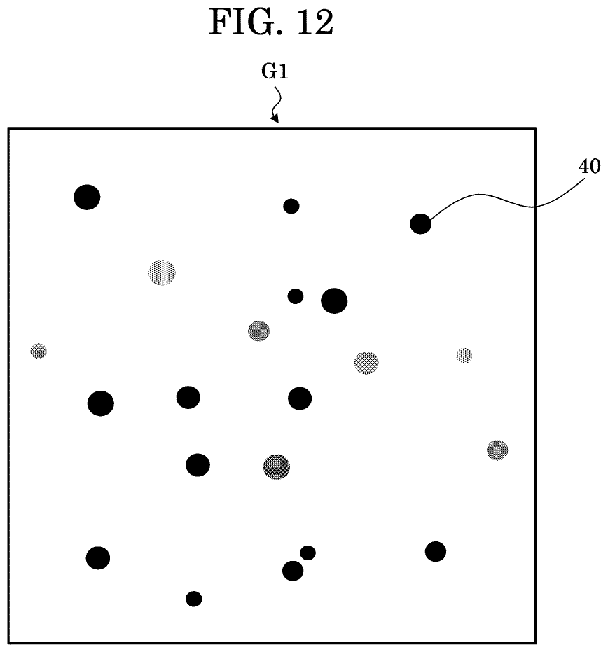

For each semiconductor devices 100 provided on the wafer 47, that is, for each chip, the identification pattern region 15 in the chip is captured using a camera or other means. The size of the identification pattern region 15 is, for example, 10 μm×10 μm. FIG. 12 is a schematic diagram of an image G1 showing the state of the needle-shaped structures 40 randomly distributed in the identification pattern region 15. Within the image G1 of the identification pattern region 15, randomly located needle-shaped structures 40 are captured. In the image G1, depending on the size of the 40 needle-shaped structures and other factors, the image has shading in the case where the image is grayscale, and color changes in the case where the image is color. Hereinafter, the image obtained by capturing the identification pattern region 15 may be referred to as an identification pattern map.

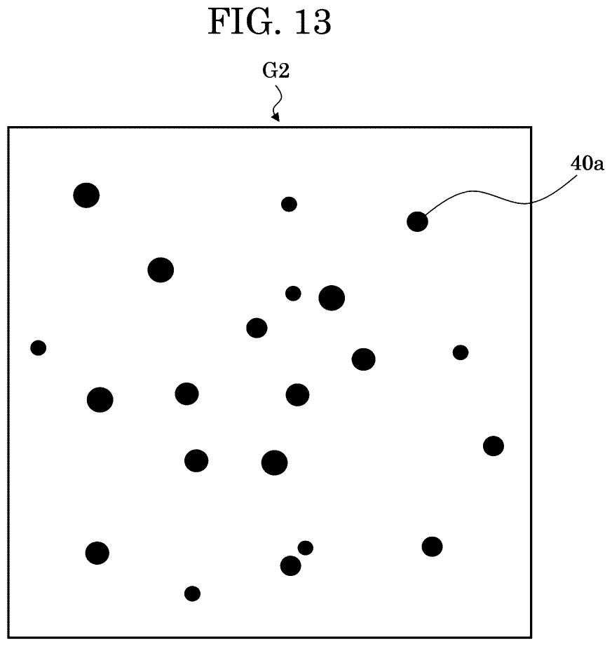

Next, the image G1 is binarized and converted into a binarized identification pattern map G2 represented black dots and a white background as shown in FIG. 13. In the grayscale image G1, the needle-shaped structures 40 has size-dependent shading, while the binarization converts the image of the needle-shaped structures 40 into black dots 40a, which is a more usable form of identification pattern on the basis of the needle-shaped structures 40.

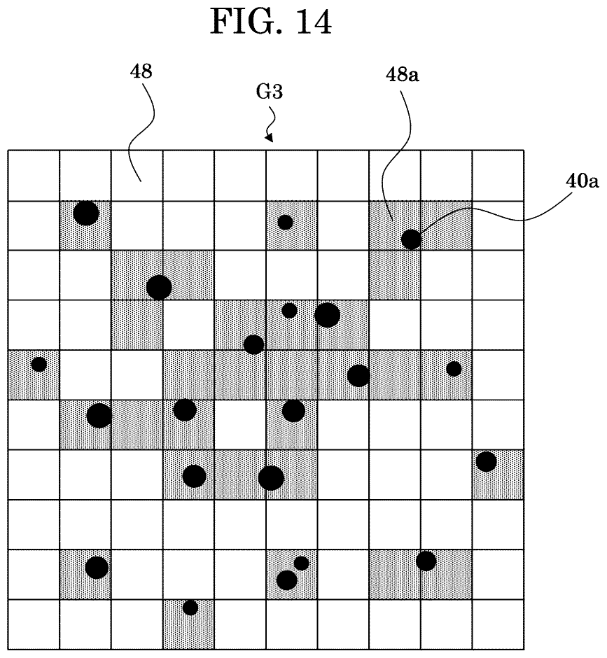

The binarized identification pattern map G2 is further partitioned. FIG. 14 is a schematic diagram showing a binarized identification pattern map G3 partitioned into 10×10 sections 48 as an example of partitioning. Since the size of the identification pattern region 15 is 10 μm×10 μm, the size of one section is 1 μm×1 μm. In the case where any part of the black dot 40a, which is binarized images of needle-shaped structure 40, exists in the section 48, the section is visualized using the filling pattern 48a to facilitate identification of the section containing the black dot 40a.

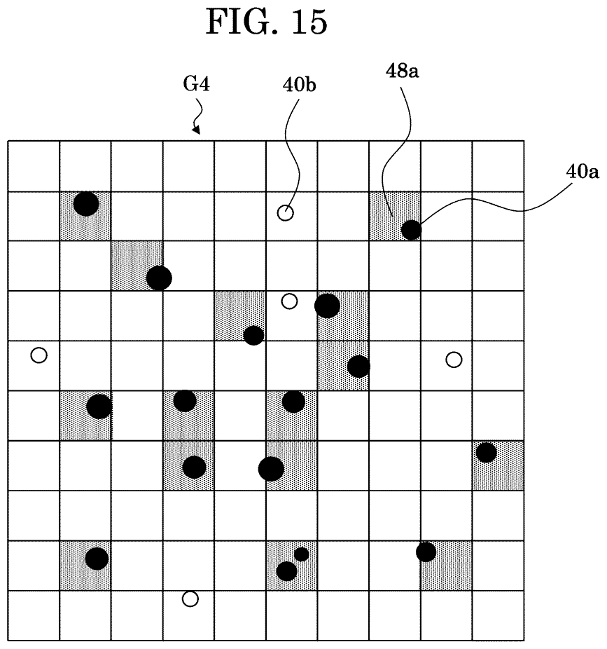

The partitioned binarized identification pattern map G3 is converted into a binarized identification pattern map G4 in which the upper limit of the number of black dots 40a in the map is set. FIG. 15 shows a schematic diagram of the binarized identification pattern map G4 in the case where the upper limit value is set to 15 as an example of setting the upper limit of the number of black dots 40a. The reason for setting such an upper limit is that, in the case where an unnecessarily large number of black dots 40a exist in one binarized identification pattern map G3, pattern recognition would be complicated and the processing time would be long.

One example of a method for setting an upper limit to the number of black dots 40a in one binarized identification pattern map G3 is to set the number of black dots 40a by ranking the black dots 40a in increasing order of area, and sorting the black dots 40a up to the upper limit in order from the highest ranking. The section containing the selected black dot 40a is visualized using the filling pattern 48a. In the case where the selected black dot 40a is located across a plurality of sections 48, only the section in which the black dot 40a has the largest area contained within the section is visualized using the filling pattern 48a.

Furthermore, the black dots 40a excluded by the selection are displayed as black dots with white background 40b, and the filling pattern 48a of the concerned section is also erased.

Since about 30 to 50 black dots 40a are expected to be generated within the 10 μm×10 μm identification pattern region 15, the number of sections in which black dots 40a exist can be set to a fixed number without excess or deficiency by sorting the upper limit number of black dots 40a as 15. This is because, as mentioned above, increasing the number of sections with black dots 40a more than necessary causes a disadvantage of increasing the processing time required to sort out the black dots 40a.

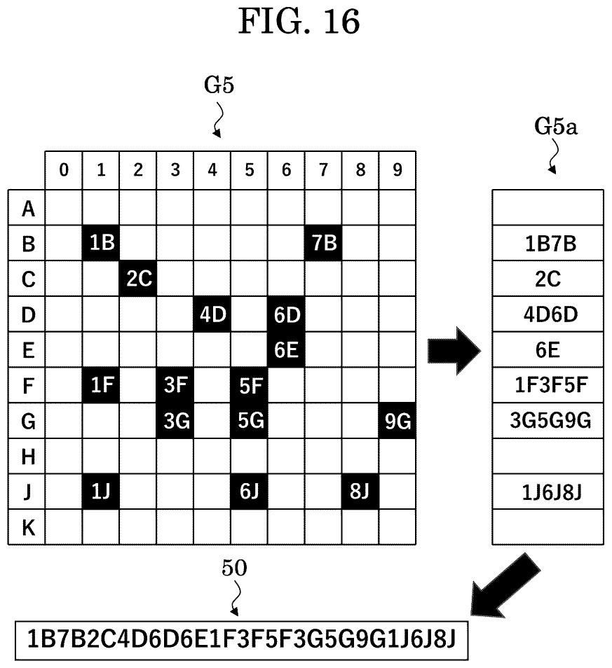

Next, the coordinates of the sections 48 of the binarized identification pattern map G4, which sets the upper limit for the number of black dots 40a in the binarized identification pattern map G3, are set. FIG. 16 shows the coordinated identification pattern map G5, which is partitioned into 10×10 sections, that is, for 10 rows×10 columns sections, with the column direction (X-axis direction) defined as coordinates 0 to 9 and the row direction (Y-axis direction) as coordinates A to K. In the coordinate setting for the row direction, “I” is skipped because it is confusing to distinguish “I” from “1”. Using such a coordinate display, for example, the black dot 40a located in the upper left corner of the binarized identification pattern map G4 shown in FIG. 15 is located in the section represented as the coordinate 1B in the coordinated identification pattern map G5 shown in FIG. 16.

The 30-digit character-string code 50 is completed by connecting all the coordinates of 15 sections including the black dots 40a, following the order from row A, column 0, to row K, column 9. As a method of connecting coordinates, first, coordinates are connected in units of rows. FIG. 16 shows a character-string list G5a in which coordinates are connected in row units. The character-string codes of the coordinates connected in row units are further connected in the order of rows to generate the 30-digit character-string code 50.

As an example of the character-string code 50, in the case where the 15 selected black dots 40a in the coordinated identification pattern map G5 are converted into a character-string code, the 30-digit character-string code 50 represented by “1B7B2C4D6D6E1F3F5F3G5G9G1J6J8J” is obtained.

The generated character-string code 50 is stored in a database (not shown). Storing the identification pattern as the character-string code 50 has an advantage of greatly reducing the data volume compared to storing the identification pattern in an image format such as the binarized identification pattern map G4.

In the generation of the character-string code 50, the probability of a phenomenon in which the completely same character-string code 50 is accidentally generated can be regarded as the probability that the coordinates of 15 sections are identical for every 100 sections which is all the number of sections in one map, and thus, expressed in permutation, is 100P15. The 100P15 is calculated to be 1/3.31×1029, which means that such probability value is as close to zero as possible. That is, the probability that the same character-string code 50 occurring between different chips is as close to zero as possible.

If the phenomenon with an extremely low probability of occurrence occurs, such as the generation of the same character-string code 50 on different chips, an error is displayed when the character-string code 50 is searched for in the database. This is because two chips which are apparently the same exist. However, even if a failure occurs where one chip among a large number of chips cannot be matched by the database due to the fact that the one chip has the same character-string code 50 as that of another chip, the failure hardly affects the production of the entire chips, and therefore, no problem occurs.

In the semiconductor device 100 according to Embodiment 1, the structure in which both side surfaces of the undoped InGaAsP active layer 21 are buried with the ridge-buried layer 26 is adopted, and thus, the effects of current constriction and improvement in heat dissipation are achieved. In the semiconductor device 100, the identification pattern region 15 having the needle-shaped structures 40 randomly located therein can be easily formed by combining the Fe-doped semi-insulating InP first current blocking layer 23 made of Fe-doped semi-insulating InP in which Fe elements are easily aggregated due to a high Fe doping concentration, and the Fe-doped semi-insulating InP second current blocking layer 24 made of Fe-doped semi-insulating InP in which Fe elements are hardly aggregated due to a low Fe doping concentration, and then etching the region corresponding to the identification pattern region 15 from the Fe-doped semi-insulating InP second current blocking layer 24 to the surface of the n-type InP substrate 20.

That is, in the method for manufacturing a semiconductor device according to Embodiment 1, it is possible to generate a random identification pattern on the basis of the needle-shaped structures 40 randomly located each time without using a transfer process as in the micro-marking method described in Patent Document 1, thus providing an effect that chip manufacturing information is automatically encrypted.

### Effects of Semiconductor Device According to Embodiment 1

As described above, according to the semiconductor device of Embodiment 1, the identification pattern region having the needle-shaped structures randomly located in each chip is provided, thus providing an effect of obtaining a semiconductor device in which each chip can be easily identified and the chip manufacturing information is automatically encrypted.

### Effects of Method for Manufacturing Semiconductor Device According to Embodiment 1

As described above, according to the method for manufacturing a semiconductor device of Embodiment 1, the identification pattern region having the needle-shaped structures randomly located in each chip can be easily formed without a transfer process, thus providing an effect that semiconductor devices that can be identified for each chip and chip manufacturing information thereof is automatically encrypted can be easily manufactured without the requirement for additional complex manufacturing processes.

### Effects of Method for Identifying Semiconductor Device According to Embodiment 1

As described above, according to the method for identifying a semiconductor device of Embodiment 1, the identification pattern region having the needle-shaped structures randomly located in each chip can be easily formed without a transfer process, thus providing an effect of easily identifying each chip of semiconductor devices in which the chip manufacturing information is automatically encrypted.

### Embodiment 2

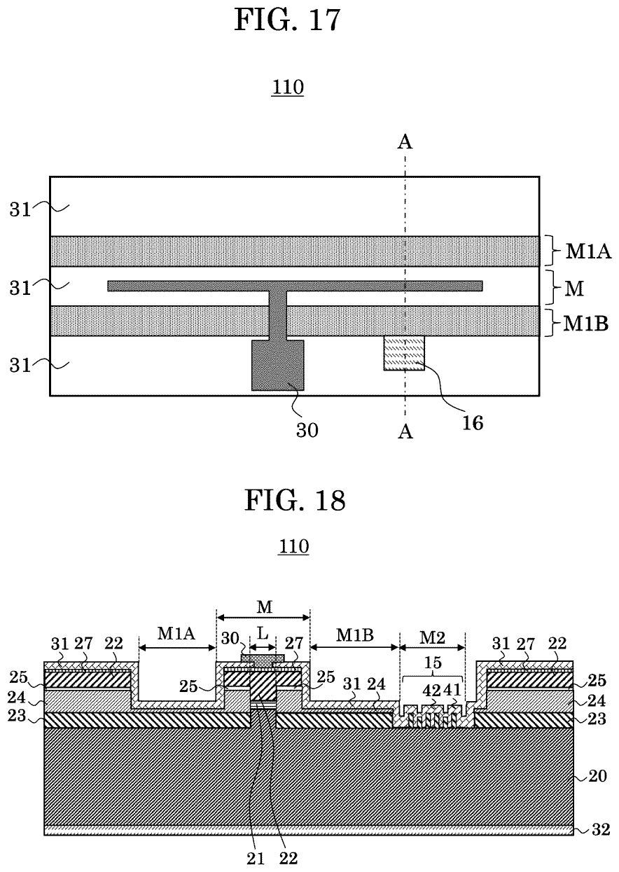

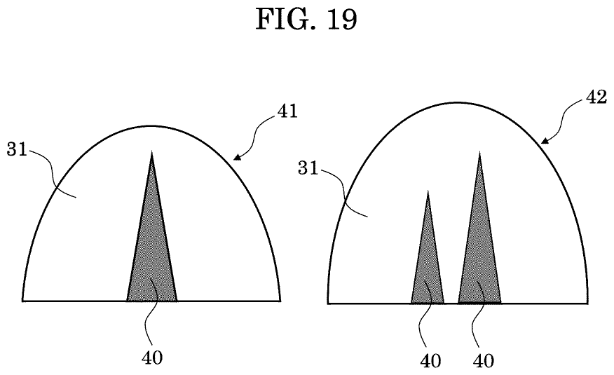

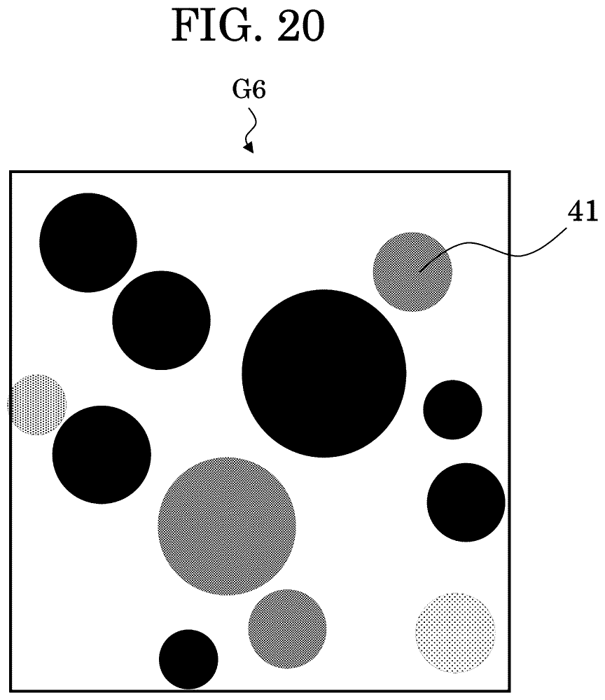

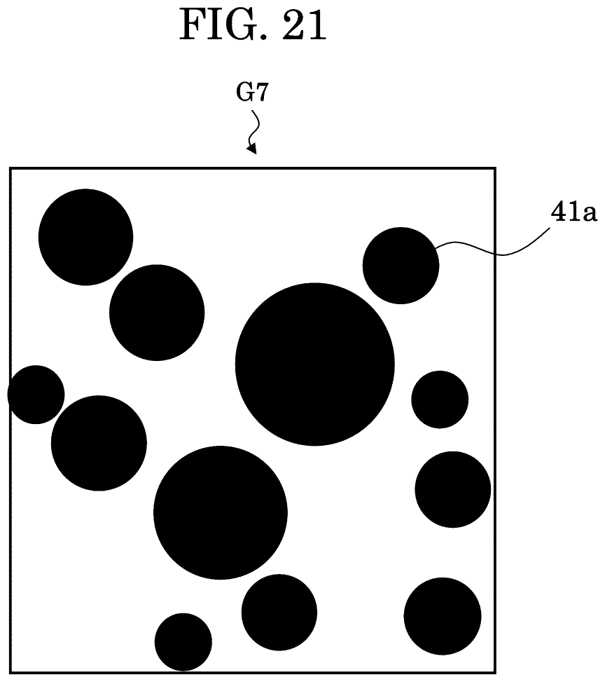

A semiconductor device 110 according to Embodiment 2 will be described with reference to FIGS. 17 to 19. FIG. 17 is a top view of a semiconductor device 110 according to Embodiment 2. FIG. 18 is a cross-sectional view of the semiconductor device 110 taken along line A-A shown in FIG. 17. FIG. 19 is a cross-sectional view of dome-shaped structures 41 randomly located within an identification pattern region 16 of the semiconductor device 110. The semiconductor device 110 according to Embodiment 2 is described below with respect to the configuration of the identification pattern region 16, which is different part from the semiconductor device 100 according to Embodiment 1.

The identification pattern region 16 of the semiconductor device 110 according to Embodiment 2 has the dome-shaped structures 41 randomly located in the identification pattern region, which is different from the identification pattern region 15 of the semiconductor device 100 according to Embodiment 1 having the needle-shaped structures 40 randomly located in the identification pattern region.

FIG. 19 is a cross-sectional view of the dome-shaped structure 41 and a dome-shaped structure 42 in the identification pattern region 16 of the semiconductor device 110. The dome-shaped structure 41 is formed by covering the needle-shaped structure 40 as a core with the SiO₂ insulating film 31. The left side of FIG. 19 shows the dome-shaped structure 41 having one needle-shaped structure 40 as the core, and the right side of FIG. 19 shows the dome-shaped structure 42 having two needle-shaped structures 40 as cores.

The reason why the dome-shaped structure 42 is formed with the two needle-shaped structures 40 as cores is that the two needle-shaped structures 40 are formed close to each other, and thus the two needle-shaped structures 40 serve as the common core to form one dome-shaped structure 42 when the needle-shaped structures 40 are covered with the SiO₂ insulating film 31 after the formation of the needle-shaped structures 40.

Consequently, in the semiconductor device 110 according to Embodiment 2, the shapes of the dome-shaped structures 41, 42 in the identification pattern region 16 have the above-described structure, and thus, the shapes of the dome-shaped structures 41, 42 are inevitably larger than the shape of the needle-shaped structure 40 of Embodiment 1. The number of the dome-shaped structures 41, 42 in the identification pattern region 16 is smaller than the number of the needle-shaped structures 40 formed in the same area. This is because there is a certain probability that a plurality of needle-shaped structures 40 form the common core to produce a single dome-shaped structure 42. Hereinafter, for convenience of description, all the dome-shaped structures are assumed to be the dome-shaped structures 41.

FIG. 20 is a schematic diagram of an image G6 showing the state of the dome-shaped structures 41 randomly distributed in the identification pattern region 16. The dome-shaped structures 41 are captured in the image G6 of the identification pattern region 16. In the image G6, depending on the size of the dome-shaped structure 41, and other factors, the image has shading in the case where the image is grayscale, and color changes in the case where the image is color.

Next, the image G6 is binarized and converted into a binarized identification pattern map G7 represented by black dots and a white background as shown in FIG. 21. In the grayscale image G6, the dome-shaped structure 41 has size-dependent shading, while the binarization converts the image of the dome-shaped structure 41 into black dots 41a, which is a more usable form of identification pattern on a basis of the dome-shaped structure 41.

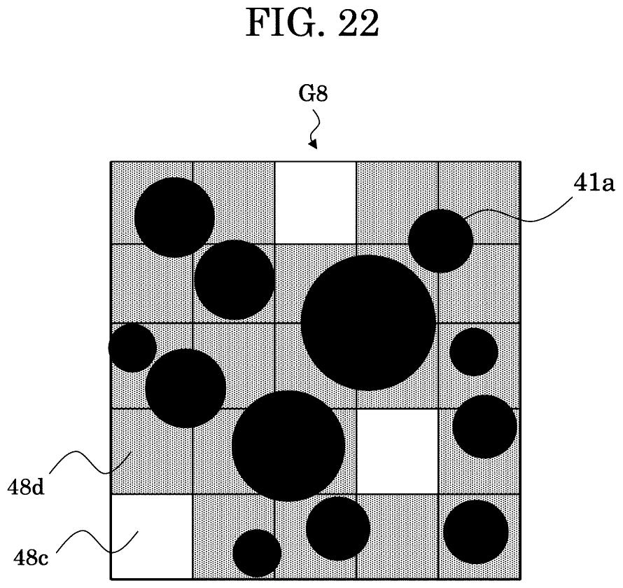

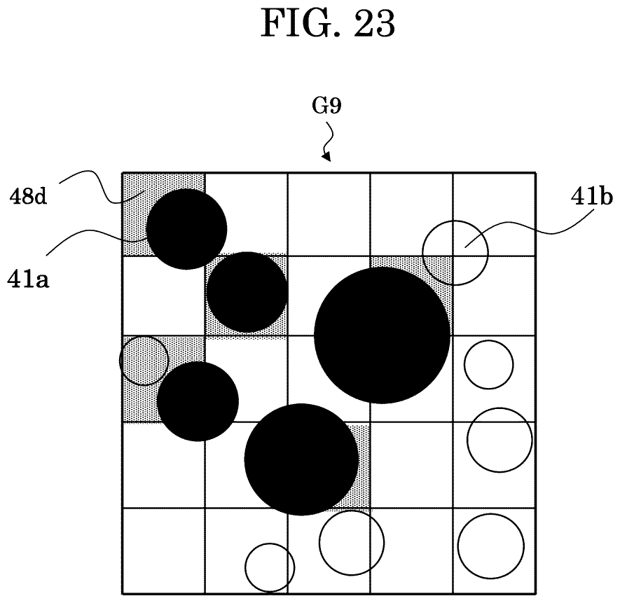

The binarized identification pattern map G7 is further partitioned. As described above, in the case where the size of the identification pattern region 16 is the same as the size of the identification pattern region 15 of Embodiment 1, the number of the dome-shaped structures 41 in the identification pattern region 16 is smaller than the number of the needle-shaped structures 40 of Embodiment 1, and the size thereof is larger. Accordingly, in Embodiment 2, the size of one section, that is, the area of one section is set to be four times the area of one section in Embodiment 1. An example of the size of the identification pattern region 16 is set at 10 μm×10 μm, which means that the size of one section is 2.0 μm×2.0 μm. FIG. 22 is a schematic diagram showing a binarized identification pattern map G8 partitioned into 5×5 sections 48c as an example of partitioning. In the case where any part of the binarized black dot 41a representing the dome-shaped structure 41 exists in the section, the section is visualized using the filling pattern 48d to facilitate identification of the section containing the black dot 41a.

The partitioned binarized identification pattern map G8 is converted into a binarized identification pattern map G9 in which the upper limit of the number of black dots 41a in the map is set. FIG. 23 is a schematic diagram showing the binarized identification pattern map G9 in the case where the upper limit value is set to 5 as an example of setting the upper limit of the number of black dots 41a. The reason why the upper limit of the number of black dots 41a is set to 5 is that the number of sections is smaller in Embodiment 2 than in Embodiment 1. Furthermore, in the case where more black dots 41a exist than necessary in one binarized identification pattern map G8, pattern recognition would be complicated and the processing time would be long.

One example of a method for setting an upper limit to the number of black dots 41a in one binarized identification pattern map G8 is, as in the case of Embodiment 1, to rank the black dots 41a in order of increasing area, and to select the black dots 41a up to the upper limit in order from the highest ranking. The section containing the selected black dot 41a is visualized using the filling pattern 48d. In the case where the selected black dot 41a is located across a plurality of sections, only the section in which the black dot 41a has the largest area contained within the section is visualized using the filling pattern 48d.

Furthermore, the black dots 41a excluded by the selection are displayed as black dots with white background 41b, and the filling pattern 48d of the concerned section is also erased.

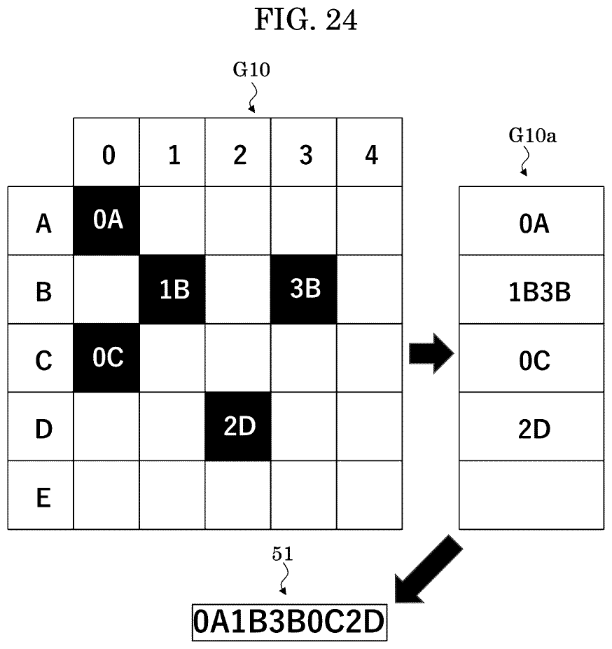

Next, the coordinates of the sections 48 of the binarized identification pattern map G9, which sets the upper limit for the number of black dots 41a in the binarized identification pattern map G8, are set. FIG. 24 shows a coordinated identification pattern map G10, with the column direction (X-axis direction) defined as coordinates 0 to 4 and the row direction (Y-axis direction) defined as coordinates A to E for 5×5 sections, that is, 5 rows×5 columns. Using such a coordinate display, for example, the black dot 41a located in the upper left corner of the binarized identification pattern map G9 shown in FIG. 23 is located in the section represented as the coordinate 0A in the coordinated identification pattern map G10.

The 10-digit character-string code 51 is completed by connecting all the coordinates of 5 sections including the black dot 41a, following the order from row A, column 0, to row E, column 4. As a method of connecting coordinates, first, coordinates are connected in row units. FIG. 24 shows a character-string list G10a in which coordinates are connected in row units. The character-string codes of the coordinates connected in row units are further connected in the order of rows to generate the 10-digit character-string code 51.

In Embodiment 2, the probability of a phenomenon in which the completely same character-string code 50 is accidentally generated between different chips can be regarded as the probability that the coordinates of 5 sections are identical for every 25 sections which is all the number of sections in one map, and thus, expressed in permutation, is 25P5. The probability is 1/6375600, and thus the probability of generating the same character-string code 51 is about one out of several million. That is, the probability that the same character-string code 51 occurring between different chips is as close to zero as possible.

The advantage of increasing the size of the structures randomly located in the identification pattern region 16 to reduce the number of the structures. That is, the advantage of forming the dome-shaped structures 41 by covering the needle-shaped structures 40 with the SiO₂ insulating film 31 is to increase the strength of the structures. In the state of the needle-shaped structure 40, there is a possibility that the needle-shaped structure 40 is damaged as a structure that disappears due to the chemical liquid treatment or is broken and destroyed due to the impact. As a result of the destruction of the needle-shaped structure 40, in the case where the character-string code 50 is generated by the same algorithm, the character-string code 50 may not match the character-string code 50 stored in the database. In contrast, the dome-shaped structure 41 applied in Embodiment 2 has a structure in which the needle-shaped structure 40 is covered with the SiO₂ insulating film 31 as shown in FIG. 19. In such a structure, the SiO₂ insulating film 31 functions as a protective film for the needle-shaped structure 40, and thus, the strength of the dome-shaped structure 41 is remarkably increased as compared with the needle-shaped structure 40 itself, so the number of cases in which the structures are destroyed by the manufacturing process or by impact is greatly reduced. Therefore, the reliability as the identification pattern is greatly improved.

In addition, since the size of the dome-shaped structure 41 is larger than the size of the needle-shaped structure 40 of Embodiment 1, the dome-shaped structure 41 can be easily identified in pattern recognition.

### Effects of Semiconductor Device According to Embodiment 2

As described above, according to Embodiment 2, the identification pattern region in which the dome-shaped structures with the needle-shaped structures as the cores and covered with the SiO₂ insulating film are randomly located is provided in the chip, thus providing an effect that the identification of each chip is further improved, and a semiconductor device with structurally more stable chip manufacturing information automatically encrypted can be obtained.

### Effects of Manufacturing Method for Semiconductor Device According to Embodiment 2

As described above, according to the method of Embodiment 2, the identification pattern region in which the dome-shaped structures formed by covering the needle-shaped structures as the cores with the SiO₂ insulating film are randomly located is formed for each chip, thus providing an effect that a semiconductor device with automatically encrypted chip manufacturing information, which further improves the identification of each chip and is structurally more stable, can be easily manufactured without the requirement for additional complex manufacturing processes.

### Effects of Method for Identifying Semiconductor Device According to Embodiment 2

As described above, according to the semiconductor device identification method of Embodiment 2, each semiconductor device is identified using an identification pattern region formed in the chip and in which dome-shaped structures are randomly located, thus providing an effect of easily identifying chip-by-chip of semiconductor devices in which chip manufacturing information is automatically encrypted.

### Embodiment 3

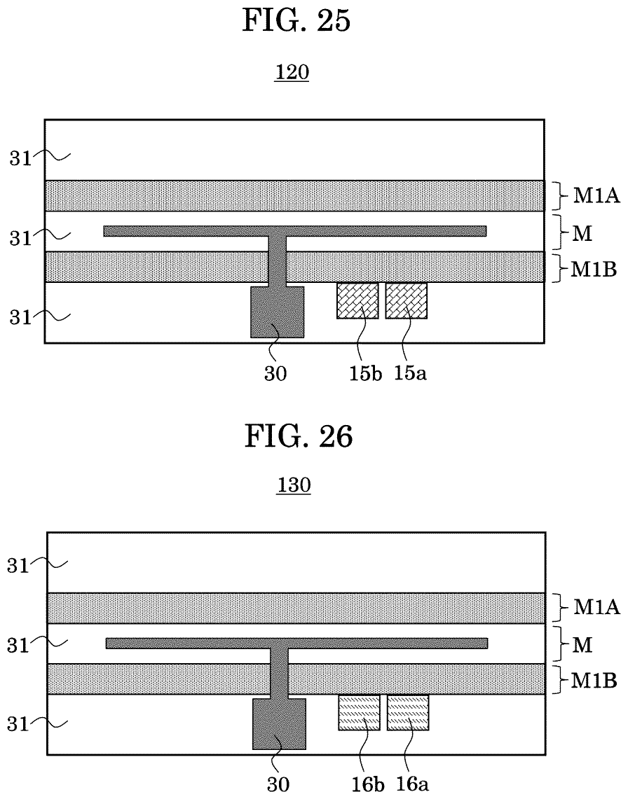

FIG. 25 is a top view of a semiconductor device 120 according to Embodiment 3. The semiconductor device 120 according to Embodiment 3 is characterized in that it has two identification pattern regions, that are, an identification pattern region 15a and an identification pattern region 15b, each having the needle-shaped structures 40 randomly located.

For the semiconductor device 120 having the identification pattern region 15a and the identification pattern region 15b, two character-string codes 50 each having 30 digits are obtained by separately identifying the two identification pattern regions 15a, 15b using the method for identifying a semiconductor device described in Embodiment 1. The use of such two character-string codes 50 allows for more stable identification of semiconductor devices, since the probability of different chips having two identical character-string codes 50 is extremely small.

### Embodiment 4

FIG. 26 is a top view of a semiconductor device 130 according to Embodiment 4. The semiconductor device 130 according to Embodiment 4 is characterized in that it has two identification pattern regions, that are, an identification pattern region 16a and an identification pattern region 16b, each having the dome-shaped structures 41 randomly located.

For the semiconductor device 130 having the identification pattern region 16a and the identification pattern region 16b, two character-string codes 51 each having 10 digits are obtained by separately identifying the two identification pattern regions 16a, 16b using the method for identifying a semiconductor device described in Embodiment 2. The use of such two character-string codes 51 allows for more stable identification of semiconductor devices, since the probability of different chips having two identical character-string codes 51 is extremely small.

In the case where the method for identifying a semiconductor device according to Embodiment 2 is applied to the semiconductor device 130, two character-string codes 51 each having 10 digits are obtained, and thus the probability that the two character-string codes 51 are exactly the same character-string code is 1/63756002, which can be reduced to a realistically improbable probability level.

### Embodiment 5

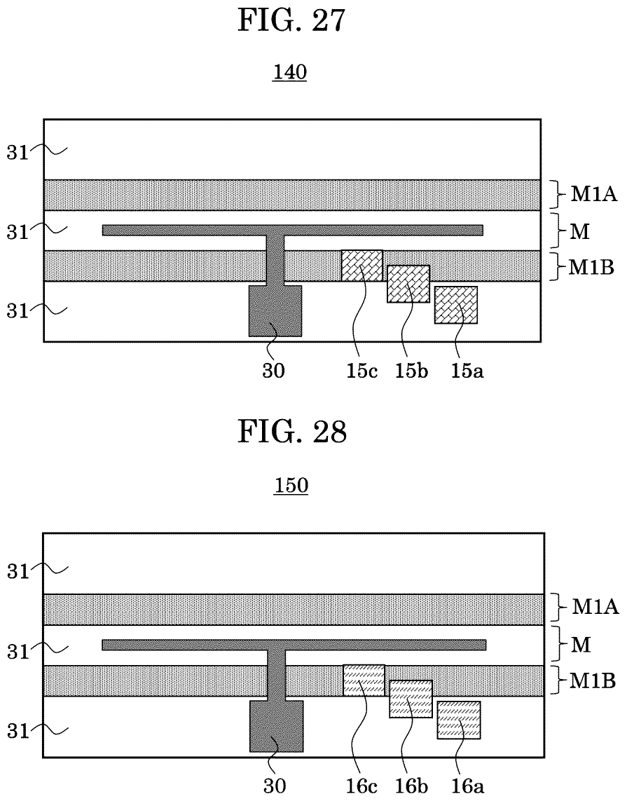

FIG. 27 is a top view of a semiconductor device 140 according to Embodiment 5. The semiconductor device 140 according to Embodiment 5 is characterized in that it has three identification pattern regions, that are, an identification pattern region 15a, an identification pattern region 15b, and an identification pattern region 15c, each having the needle-shaped structures 40 randomly located. The identification pattern region 15a is provided so as to be separated from the mesa-stripe groove M1B. The identification pattern region 15b is provided so as to overlap with the mesa-stripe groove M1B by about half. The identification pattern region 15c is provided so as to completely overlap with the mesa-stripe groove M1B.

For the semiconductor device 140 having the identification pattern region 15a, the identification pattern region 15b, and the identification pattern region 15c, three character-string codes 50 each having 30 digits are obtained by separately identifying the three identification pattern regions 15a, 15b, 15c using the method for identifying a semiconductor device described in Embodiment 1. The use of such three character-string codes 50 allows for more stable identification of semiconductor devices, since the probability of different chips having three identical character-string codes 50 is extremely small.

### Embodiment 6

FIG. 28 is a top view of a semiconductor device 150 according to Embodiment 6. The semiconductor device 150 according to Embodiment 6 is characterized in that it has three identification pattern regions, that are, an identification pattern region 16a, an identification pattern region 16b, and an identification pattern region 16c, each having the dome-shaped structures 41 randomly located. The identification pattern region 16a is provided so as to be separated from the mesa-stripe groove M1B. The identification pattern region 16b is provided so as to overlap with the mesa-stripe groove M1B by about half. The identification pattern region 16c is provided so as to completely overlap with the mesa-stripe groove M1B.

For the semiconductor device 150 having three identification pattern regions, three character-string codes 51 each having 10 digits are obtained by separately identifying the three identification pattern regions 16a, 16b, 16c using the method for identifying a semiconductor device described in Embodiment 2. The use of such three character-string codes 51 allows for more stable identification of semiconductor devices, since the probability of different chips having three identical character-string codes 51 is extremely small.

### Embodiment 7

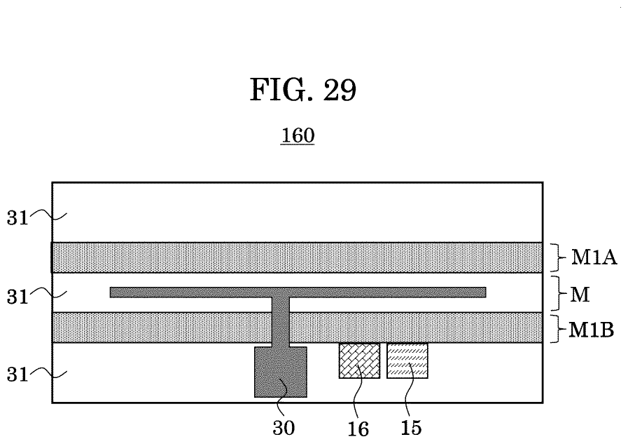

FIG. 29 is a top view of a semiconductor device 160 according to Embodiment 7. The semiconductor device 160 according to Embodiment 7 is characterized in that it has two identification pattern regions in which different types of structures are located, that are, the identification pattern region 15 having the needle-shaped structures 40 randomly located in the region and the identification pattern region 16 having the dome-shaped structures 41 randomly located in the region.

In the semiconductor device 160, it is possible to use the identification pattern region 15 with the needle-shaped structures 40, which provides relatively more identification information necessary for semiconductor device identification but lacks structural stability, and the identification pattern region 16 with the dome-shaped structures 41, which provides relatively less identification information necessary for semiconductor device identification but has excellent structural stability, in a complementary manner, and thus enables more stable identification of semiconductor devices.

### Embodiment 8

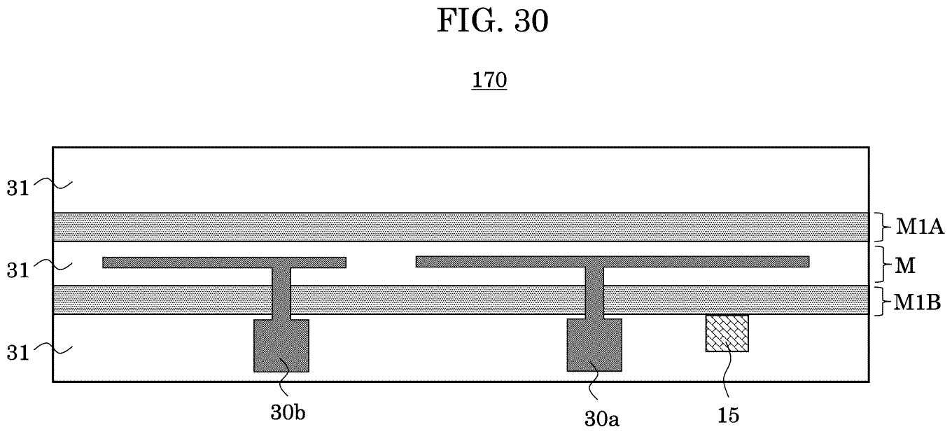

FIG. 30 is a top view of a semiconductor device 170 according to Embodiment 8. The semiconductor device 170 according to Embodiment 8 is an EML device in which a modulator (EA) unit is further integrated in the semiconductor device 100 according to Embodiment 1. In FIG. 30, the region where the front surface electrode 30a is formed is the semiconductor laser portion, and the region where the front surface electrode 30b is formed is the modulator portion.

The semiconductor device 170 according to Embodiment 8 enables easy identification of the EML devices having the modulator portion and the semiconductor laser portion.

### Embodiment 9

A method for identifying a semiconductor device according to Embodiment 9 will be described in terms of differences from the methods for identifying a semiconductor device according to Embodiment 1 and Embodiment 2. The method for identifying a semiconductor device according to Embodiment 9 is designed to be used in the actual manufacturing industry in general with respect to further utilization of the character-string code obtained in Embodiment 1 and Embodiment 2.

In Embodiment 1 and Embodiment 2, the images of the identification pattern regions 15, 16 are mapped, and thus the character-string codes 50, 51 are generated by defining coordinates in the upper sections. However, it may be impractical to reproduce 100% of character-string codes due to a failure such as shifting of the image capture position or focus.

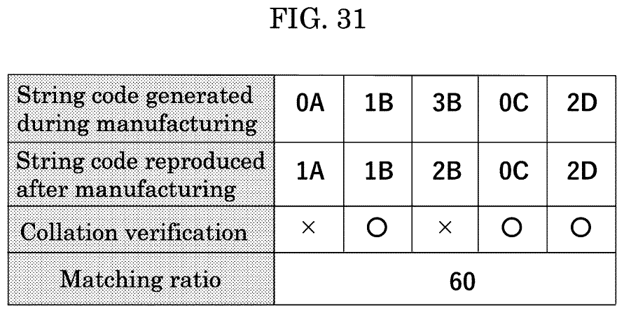

FIG. 31 shows a process for calculating a matching rate between the character-string code generated at the time of the manufacturing semiconductor devices and the character-string code reproduced after the manufacturing in the case of Embodiment 2. Each combination of numbers and alphabets indicating each coordinate is compared with the same digits as a single piece of information. The ratio of coordinates matched by the collation is a matching rate. In the collation check shown in FIG. 31, circled and crossed marks indicate cases where there is a match between each coordinate of the character-string code 51 at the time of manufacturing and the character-string code 51 restored after manufacturing, and cases where there is no matching, respectively. In the example of the collation shown in FIG. 31, the matching rate between the character-string code 51 at the time of manufacturing and the character-string code 51 restored after manufacturing is 60%.

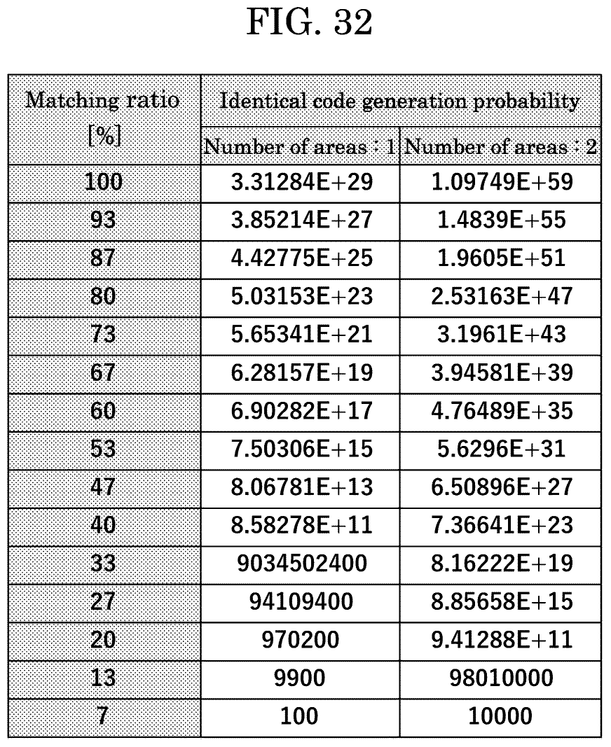

FIG. 32 is a table showing the probability that the same character-string code 50 is generated in another semiconductor device in the case where the matching rate of the character-string code 50 is lowered in Embodiment 1. The number of areas in FIG. 32 indicates the number of identification pattern regions. In FIG. 32, the reciprocal of the numerical value representing the probability is shown for convenience. Consequently, the actual probability is obtained by dividing the numerical value in the figure by 1.

For example, in the case where the number of the identification pattern regions 15 in which the needle-shaped structures 40 are formed is one, if the matching rate is at least 33% or more, the probability that the same character-string code 50 is generated among a plurality of semiconductor devices is about 1/9 billion. In the case where the number of the identification pattern regions 15 in which the needle-shaped structures 40 are formed is two, the probability that the same character-string code 50 is generated among a plurality of semiconductor devices is about 1/900 billion even when the matching rate is 20% or more, which is as close to zero as possible.

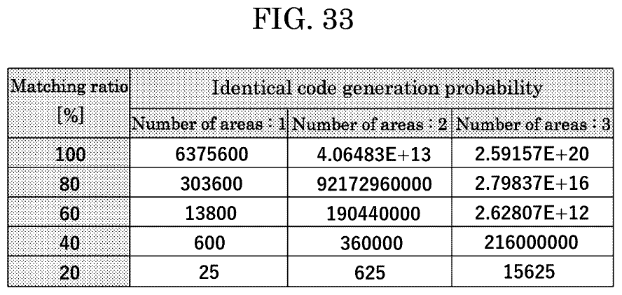

FIG. 33 is a table showing the probability that the same character-string code 51 is generated in another semiconductor device in the case where the matching rate of the character-string code 51 is lowered in Embodiment 2. The number of areas in FIG. 33 indicates the number of identification pattern regions 16. For example, in the case where the number of the identification pattern regions 16 in which the dome-shaped structures 41 are formed is two, if the matching rate is at least 60% or more, the probability that the same character-string code 51 is generated among a plurality of semiconductor devices is about 1/200 million. In the case where the number of the identification pattern regions 16 in which the dome-shaped structures 41 are formed is three, the probability that the same character-string code 51 is generated among a plurality of semiconductor devices is about 1/200 million even when the matching rate is 40% or more.

In the method for identifying a semiconductor device according to Embodiment 3, in addition to the use of the method for identifying a semiconductor device according to Embodiment 1 or Embodiment 2, in the case where a shipped semiconductor device is returned due to some failure, the character-string code is reproduced by the same algorithm as that at the time of manufacturing and is collated with the character-string code stored in the database, thus providing an effect that chip manufacturing information such as a wafer process history and an in-house test result can be confirmed, and products having a possibility of causing similar failures can be quickly collected without missing.

It is also enabled to estimate the causes of failures and to provide feedback to the manufacturing process to prevent similar failures in products to be manufactured in the future. In the manufacturing stage, test results in the chip state and test results after assembly into modules, or the like, can be linked and thus managed on a chip-by-chip basis, making it possible to remove defective products in the front-end process and simplify testing, thereby improving productivity.

### Effects of Methods for Identifying Semiconductor Device According to Embodiments 1 to 3

According to the methods for identifying a semiconductor device disclosed in the present disclosure, it is easy to link individual chips to the wafer process, which enables the history of defective chips to be confirmed and efficient feedback to be applied to the manufacturing process, thus providing an effect of improving the efficiency of quality improvement of semiconductor devices and enabling prompt response to claims. Furthermore, it is easy to compare the chip test results of semiconductor devices with the test results of semiconductor devices in the module state after assembly on a chip-by-chip basis, thus providing an effect of simplifying inspections and reducing component loss costs in post-processing.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

15, 15a, 15b, 15c, 16, 16a, 16b, 16c identification pattern region
20 n-type InP substrate
21 undoped InGaAsP active layer
21a undoped AlGaInAs active layer
22 p-type InP cladding layer
23 Fe-doped semi-insulating InP first current blocking layer
24 Fe-doped semi-insulating InP second current blocking layer
25 n-type InP anti-diffusion layer
25a undoped InP anti-diffusion layer
26 ridge-buried layer
27 p-type InGaAsP contact layer
30, 30a, 30b front surface electrode
31 insulating film
32 back surface electrode
40 needle-shaped structure
40a, 41a black dot
40b, 41b black dot with white background
41, 42 dome-shaped structure
46 semiconductor device array
47 wafer
48, 48c section
48a 48d filling pattern
50, 51 character-string code
100, 100a, 110, 120, 130, 140, 150, 160, 170 semiconductor device

1. A semiconductor device comprising:
a semiconductor substrate;
semiconductor layers formed on the semiconductor substrate;
an identification pattern region provided in a predetermined portion on the semiconductor substrate; and
a plurality of structures formed at random positions within the identification pattern region.

2. The semiconductor device according to claim 1, wherein
the semiconductor substrate is a first-conductivity-type InP substrate, and
the semiconductor layers includes: a stripe-shaped ridge structure formed on the first-conductivity-type InP substrate and composed of a part of the first-conductivity-type InP substrate, an active layer, and a second-conductivity-type InP cladding layer; a ridge-buried layer composed of at least a Fe-doped semi-insulating InP first current blocking layer and a Fe-doped semi-insulating InP second current blocking layer to be buried in both side surfaces of the ridge structure; and a remaining portion of the second-conductivity-type InP cladding layer and a second-conductivity-type contact layer formed on a top surface of the ridge structure and a surface of the ridge-buried layer, and
mesa-stripe grooves centered on the ridge structure and reaching from the second-conductivity-type contact layer into the Fe-doped semi-insulating InP first current blocking layer are formed on both sides of the ridge structure.

3. The semiconductor device according to claim 2, wherein
the Fe doping concentration of the Fe-doped semi-insulating InP first current blocking layer is higher than the Fe doping concentration of the Fe-doped semi-insulating InP second current blocking layer.

4. The semiconductor device according to claim 2, wherein
the identification pattern region is provided adjacent to one of the mesa-stripe grooves in a top view.

5. The semiconductor device according to claim 2, wherein
the identification pattern region is provided so as to overlap one of the mesa-stripe grooves in a top view.

6. The semiconductor device according to claim 2, wherein
the identification pattern region is provided to be separated from the mesa-stripe grooves in a top view.

7. The semiconductor device according to claim 1, wherein
the structures are either one or both of needle-shaped structures and dome-shaped structures composed of the needle-shaped structures covered with an insulating film.

8. The semiconductor device according to claim 7, wherein
the needle-shaped structures are made of at least indium phosphide.

9. The semiconductor device according to claim 7, wherein
the identification pattern region is provided in a plurality, the dome-shaped structures are formed in a part of the plurality of identification pattern regions, and the needle-shaped structures are formed in the remaining part of the plurality of identification pattern regions.

10. A method for manufacturing a semiconductor device comprising:
crystal-growing sequentially an active layer and a second-conductivity-type InP cladding layer on a first-conductivity-type InP substrate;
forming a stripe-shaped ridge structure by etching a part of the first-conductivity-type InP substrate, the active layer, and the second-conductivity-type InP cladding layer;
crystal-growing a ridge-buried layer composed of at least a Fe-doped semi-insulating InP first current blocking layer and a Fe-doped semi-insulating InP second current blocking layer so as to bury on both side surfaces of the ridge structure;
crystal-growing sequentially a remaining portion of the second-conductivity-type InP cladding layer and a second conductivity type contact layer on a top surface of the ridge structure and a surface of the ridge-buried layer;
etching mesa-stripe grooves reaching from the second-conductivity-type contact layer into the Fe-doped semi-insulating InP second current blocking layer on both sides of the ridge structure, and simultaneously forming an opening portion in the region predetermined for the identification pattern region; and
etching away the Fe-doped semi-insulating InP second current blocking layer and the Fe-doped semi-insulating InP first current blocking layer in the opening portion and simultaneously forming needle-shaped structures.

11. The method for manufacturing a semiconductor device according to claim 10, wherein
dome-shaped structures are formed by covering the needle-shaped structures with an insulating film.

12. The method for manufacturing a semiconductor device according to claim 10, wherein
the Fe doping concentration of the Fe-doped semi-insulating InP first current blocking layer is higher than the Fe doping concentration of the Fe-doped semi-insulating InP second current blocking layer.

13. A method for identifying a semiconductor device comprising:
capturing an image of the identification pattern region from the top surface of the semiconductor device according to claim 1;
converting the image into a binarized map;
ranking each black dot in the binarized map higher the larger the area of the black dot on a basis of the area of the black dot; and
selecting a predetermined number of black dots from each of the ranked black dots in order of rank.

14. The method for identifying a semiconductor device according to claim 13, wherein
the identification pattern region is partitioned into a plurality of sections, and whether or not the black dot exist is determined for each section.

15. The method for identifying a semiconductor device according to claim 14, wherein
the coordinates of each partitioned section are set respectively, and character-string codes are generated by combining the coordinates of each section in which each black dot exists on a basis of the specified rule.

16. The method of identifying a semiconductor device according to claim 15, wherein
a matching rate is calculated by data comparing the character-string codes generated at the time of manufacturing the semiconductor devices with the character-string codes restored after manufacturing the semiconductor devices, and thus determination is performed on a basis of the matching rate.
